(19) United States
(12) Patent Application Publication
(10) Pub. No.: US 2026/0213143 A1
(43) Pub. Date: Jul. 23, 2026

(54) DEVICE AND METHOD FOR DETECTING THE INTENSITY OF A PLASMA EMISSION

(71) Applicant: RUHR-UNIVERSITÄT BOCHUM, Bochum (DE)

(72) Inventors: Ihor KOROLOV, Herne (DE); Felix Julian SCHULZE, Hattingen (DE); David Alexander SCHULENBERG, Bochum (DE); Florian BECKFELD, Bochum (DE)

(21) Appl. No.: 19/138,778

(22) PCT Filed: Dec. 14, 2023
(86) PCT No.: PCT/EP2023/085902

§ 371 Date: Jun. 13, 2025

(30) Foreign Application Priority Data
Dec. 14, 2022 (DE) 10 2022 133 333.7

(51) Int. Cl. H01J 37/32; G01J 1/04; G01J 1/44

(52) U.S. Cl. CPC H01J 37/32935; G01J 1/0425; G01J 1/44; G01J 2001/4453; H01J 2237/2445; H01J 2237/24507

(57) ABSTRACT

The disclosure relates to a method for detecting the intensity of an emission of a plasma which can be generated in a plasma-generating device. According to an implementation, received voltage signals of a photomultiplier are assigned to a respective duration within a period of a periodic signal of the plasma-generating device using at least one received synchronization signal. The disclosure additionally relates to an analysis unit for carrying out the aforementioned method and to a device for detecting the intensity of an emission of a plasma which can be generated in a plasma-generating device, including the plasma-generating device, a photomultiplier, a synchronization signal generator, and the aforementioned analysis unit.

### INTRODUCTION

The disclosure relates to a method for detecting an intensity of an emission of a plasma generated in a plasma-generating device.

The disclosure furthermore relates to an evaluation unit configured to carry out the above method.

The disclosure furthermore relates to a device for detecting an intensity of an emission of a plasma that can be generated in a plasma-generating device, including the above evaluation unit.

Plasmas are used in the semiconductor industry, for example, to apply layers a few nanometers thick onto silicon wafers or to etch other structures in the same order of magnitude into the wafer. To monitor and control the plasma processes and also to develop better plasma processes, there is demand for technologies for monitoring the plasma. Thus, for example, process drifts, which are induced by changes of the wall conditions in the plasma chamber, are a problem in the processing of wafers. One possible form of such a process drift is known by the name “first wafer effect”.

One possibility for monitoring plasma processes is phase resolved optical emission spectroscopy (PROES), which permits location-resolved and time-resolved measurement of the electron dynamics in the plasma. PROES is based on measuring the emission of the plasma using an ICCD camera (intensified-charge coupled device camera), thus a camera which uses a CCD sensor (charge-coupled device) as an image sensor, to which, for example, a microchannel plate is coupled by an optical fiber to increase the sensitivity. This type of camera permits exposure times of less than 1 ns; accordingly the plasma can be optically detected in a location-resolved and time-resolved manner within a period of the AC voltage using which the plasma is generated, which is typically approximately 74 ns (corresponding to a frequency of 13.56 MHz), and the plasma emission can be measured in this way.

However, PROES has the disadvantage that ICCD cameras are very expensive, so that the technology is linked to high acquisition costs. Moreover, PROES presumes a free field of vision for the camera onto the plasma. Accordingly, the chamber of the plasma-generating device has to have a sufficiently large viewing window. These viewing windows are generally not present in plasma-generating devices in industry. For several reasons, installing a viewing window in plasma-generating devices in industry for the purpose of carrying out PROES using an ICCD camera is precluded: On the one hand, it would be accompanied by costly refitting of the chambers, or even new acquisitions. On the other hand, the input parameters such as gas mixture, gas pressure, the power output by the generators, etc., which are required to structure the wafer in a specific manner, also called “recipes”, would have to be redetermined. These recipes are determined by the producers of plasma-generating devices with great effort and are purchased at a high price by industry. The use of ICCD cameras for PROES would thus be linked with massive investments and structural changes. For these reasons, it is advantageous if new systems for process monitoring can be integrated into the existing infrastructure and are minimally invasive.

Alternative technologies for carrying out phase-resolved optical emission spectrometry are described in the technical articles “Evidence for a time dependent excitation process in silane radio frequency glow discharges” by G. de Rosny et al. (Journal of Applied Physics 54, 2272 (1983); DOI: 10.1063/1.332381) and “Time- and space-resolved spectroscopy of electron transport in low-frequency discharge plasma in argon” by T. Makabe and M. Nakaya (Journal of Physics D: Applied Physics 20, 1243 (1987); DOI: 10.1088/0022-3727/20/10/006). In this case, a photoelectron multiplier—also called a photomultiplier or PMT (photomultiplier tube)—is used in each case to measure the emissions originating from the plasma.

With respect to measuring the signal of the PMT, de Rosny et al. teach measuring the time difference between the rising flank of the voltage pulse generated by the PMT and the next zero crossing of the measured AC voltage, using which the plasma is generated, and plotting it in a histogram, from which the time-resolved emission of the plasma results. Makabe and Nakaya, in contrast, describe tapping the signal of the PMT in short time windows using a sampling gate and achieving time resolution in this way. To achieve location resolution, it is necessary in both technologies described in the technical articles to displace the PMT with respect to the plasma. In both technologies, the PMT has been detached from an ICCD camera in the meantime, since the use of an ICCD camera permits a higher location resolution.

### SUMMARY

Proceeding therefrom, it is the object of the disclosure, per an embodiment, to provide means which simplify and/or improve the monitoring of plasma processes.

According to the disclosure, per an embodiment, a method for detecting an intensity of an emission of a plasma generated in a plasma-generating device is provided, comprising the following steps
receiving chronologically successive voltage signals of a photomultiplier used for detecting optical signals of the plasma,
receiving at least one synchronization signal correlating with a periodic signal of the plasma-generating device,
assigning the received voltage signals to a respective time interval within a period of the periodic signal with the aid of the received synchronization signal, and
determining the intensity by summing a number of voltage signals assigned to the respective time interval.

The object is moreover achieved, per an embodiment, by an evaluation unit of a device for detecting an intensity of an emission of a plasma that can be generated in a plasma-generating device, wherein the evaluation unit is configured to carry out the above method.

Furthermore, the disclosure, per an embodiment, relates to a device for detecting an intensity of an emission of a plasma that can be generated in a plasma-generating device, comprising the plasma-generating device, a photomultiplier, a synchronization signal generator, and the above evaluation unit,
wherein the plasma-generating device comprises a chamber for providing the plasma and a generator for generating a periodic signal and is designed to generate a plasma in the chamber,
wherein the chamber is connected via an optical passage to the photomultiplier such that an optical signal generated by the plasma is transmittable to the photomultiplier,
wherein the photomultiplier is configured to generate a voltage signal on the basis of the optical signal,
wherein the synchronization signal generator is configured to generate at least one synchronization signal correlating with the periodic signal, and
wherein the evaluation unit is connected to the photomultiplier to receive the voltage signal and is connected to the synchronization signal generator to receive the synchronization signal.

One aspect of the disclosure, per an embodiment, is that the voltage signals generated by the photomultiplier are assigned in the evaluation unit to the respective time interval within the period of the periodic signal with the aid of the synchronization signal. A histogram of the emission intensity over a period of the periodic signal results in this way. The periodic signal is preferably a periodic high-frequency signal, particularly preferably a signal having a frequency between 1 MHz and 100 MHz. In other words, it is thus provided that each photon detected as a voltage signal is assigned to a time interval—also called a bin—within the period of the periodic signal with the aid of the synchronization signal. The voltage signals are particularly preferably assigned in the evaluation unit with the aid of the synchronization signal of the phase of the periodic signal, in order to generate the histogram in this way, wherein it is furthermore preferably provided that the length of the time interval—which is also referred to as the binwidth—is predefined. The length of the time interval is selected such that a sufficient resolution is achieved and is preferably between 1 ns and 5 ns. In other words, the electrode dynamics of the plasma are thus measured in a time-resolved manner by means of a method similar to time-correlated single photon counting. Time-correlated single photon counting is also used, among other things, in measuring the fluorescence lifetime of various life sources. In this case, after a “start” signal, the time difference until a “stop” signal, triggered by a voltage signal of a photomultiplier, for example, is counted. A histogram results by frequent repetition of this method, for example of the chronologically resolved fluorescence of the light source. The present disclosure, per an embodiment, now differs from previous methods for time-correlated single photon counting in that the data recording is not stopped after the measurement of a voltage signal generated by a photon, but rather all signals which the photomultiplier outputs are assigned to the respective period over a specific number of periods of the synchronization signal and/or over a specific time. The present method has the advantage, per an embodiment, that it is also possible to detect the intensity of the emission of the plasma when only a very low intensity is present. For example, only a single photon over several hundred periods of the periodic signal can also arrive at the photomultiplier. This only has the result that the data recording takes longer. Moreover, it is also not necessary for a photomultiplier having a particularly short reaction time to be used, since an assignment of the voltage signal to the corresponding time interval of the periodic signal is carried out by means of the synchronization signal. If a photomultiplier having a short reaction time is used, the method permits a significant reduction of the measuring time in relation to known methods, since in this way multiple photons can also be measured per period of the periodic signal.

In contrast to the method described in the technical article by Makabe and Nakaya, in the present case, per an embodiment, the period of an applied trigger signal is thus not run using a sampling gate. Instead, all incoming photons—or all voltage signals resulting therefrom at the photomultiplier—are assigned to the respective time interval of the period of the periodic signal.

Likewise, the voltage signal generated by the photon incoming at the photomultiplier is not used in the present method, as in the technical article by G. de Rosny et al., to start a measurement as a “start” signal, which is then ended by a “stop” signal chronologically correlating with the periodic signal.

The present disclosure, per an embodiment, has the advantage over the methods described in the technical articles by Makabe and Nakaya and by G. de Rosny that it permits a significantly shorter measuring time and has a high signal-to-noise ratio.

A further aspect of the disclosure, per an embodiment, is that the chamber of the plasma-generating device is connected via the optical passage to the photomultiplier. The chamber is thus preferably free of a viewing window, as is necessary for PROES with ICCD cameras. Since industrially used plasma-generating devices are generally equipped with devices for chronologically and positionally averaged optical emission spectroscopy, which also includes an optical passage, it is particularly simple to use the method in the plasma-generating device present in industry, since both technologies use the same connection. In contrast to the chronologically and positionally averaged optical emission spectroscopy, in which only individual emission lines of the plasma are observable, however, the present method enables an analysis of the so-called electron heating mode of the plasma.

A synchronization signal is understood in the scope of the present application as a signal which can be used for synchronization and chronologically correlates with the periodic signal. The synchronization signal can itself be a periodic signal, for example a sinusoidal signal or a rectangular signal. In this case, it is preferably provided that the period of the periodic signal corresponds to the period of the synchronization signal. The periodic synchronization signal can also be understood as a sequence of multiple pulses, wherein the sequence chronologically correlates with the periodic signal. Alternatively, it is possible that the synchronization signal is not a sequence of multiple pulses, but rather is formed as a single pulse, by means of which the starting time of the measurement can be synchronized.

The photomultiplier for detecting optical signals is preferably operated in the photon counting mode. The photon counting mode is also called the digital operating mode or pulse mode. Depending on the requirements, a photomultiplier can be operated either in the current mode (current or DC mode) or in the photon counting mode (pulse mode). In the current mode, the charge of the electrons is measured at the anode and integrated over time to form an average current value. In the photon counting mode, the signal across a resistor is measured as a voltage. The photomultiplier is thus accordingly configured to generate the voltage signal on the basis of the optical signal.

An optical signal is understood in the present case as a signal having a wavelength between 100 nm and 1000 nm. The optical signal is preferably an emission of the plasma in the wavelength range from 350 nm to 900 nm.

With respect to the method, it is provided according to a preferred refinement of the disclosure, per an embodiment, that in a first alternative, the step of receiving at least one synchronization signal correlating with the periodic signal of the plasma-generating device comprises receiving multiple pulses chronologically correlating with the periodic signal of the plasma-generating device or receiving a periodic synchronization signal over multiple periods and the step of assigning the received voltage signals to the respective time interval within the period of the periodic signal with the aid of the received synchronization signal comprises assigning the received voltage signals to the respective time interval within the period of the periodic signal with the aid of the multiple pulses or with the aid of the periodic synchronization signal. In other words, in this design it is thus provided that the synchronization signal itself is designed as a periodic synchronization signal, which is received over multiple periods, and/or that the synchronization signal comprises multiple chronologically successive pulses chronologically correlating with the periodic signal. This makes the method particularly accurate, since in this way possible irregularities in the periodic signal are also taken into consideration in the assignment.

Alternatively, per an embodiment, it is preferably provided that the step of receiving at least one synchronization signal correlating with the periodic signal of the plasma-generating device comprises receiving a starting phase signal of the plasma-generating device and the step of assigning the received voltage signals to the respective time interval within the period of the periodic signal with the aid of the received synchronization signal comprises assigning the received voltage signals to the respective time interval within the period of the periodic signal with the aid of the received starting phase signal, to a time of the received voltage signal, and to a period duration of the periodic signal. In other words, in this design it is thus provided that the starting phase signal of the periodic signal is only received at the beginning of the measurement. The assignment of the received voltage signals to the respective time interval within the period then takes place by means of the knowledge about the period duration of the periodic signal and the time of the received voltage signal.

Moreover, per an embodiment, it is preferably provided that the step of receiving the chronologically successive voltage signals of the photomultiplier used for detecting the optical signals of the plasma comprises receiving the chronologically successive voltage signals of the photomultiplier used for detecting the optical signals of the plasma over a predefined integration time. In particular in conjunction with the above first-mentioned alternative, it is furthermore preferably provided that the step of receiving the multiple synchronization signals correlating with the periodic signal of the plasma-generating device takes place over the same predefined integration time.

Furthermore, per an embodiment, it is preferably provided that the steps of the method for improving a signal strength are repeatable. Repeatedly carrying out the measurement is preferably applied if sufficiently many voltage signals were not received after the maximum integration time of the evaluation unit. The method can then be repeated, wherein the voltage signals are added here to the originally generated histogram until a satisfactory signal strength is reached.

With respect to the device for detecting the intensity of an emission of a plasma that can be generated in a plasma-generating device, it is provided according to one preferred refinement of the disclosure, per an embodiment, that the synchronization signal generator is formed by the generator. In this design, the synchronization signal preferably corresponds to the signal which is output by the generator of the plasma-generating device via a synchronization output. This has the advantage that no additional device has to be used to generate the synchronization signal, since this task is taken over by the generator itself.

Alternatively thereto, per an embodiment, it is provided according to a further preferred refinement that the synchronization signal generator is formed by a voltmeter connected to the chamber. In this preferred alternative, it is thus provided that the synchronization signal is generated by a time-resolved measurement of the voltage applied at the chamber by means of the voltmeter. This has the advantage that a synchronization signal can be generated even in generators without synchronization output.

With respect to the method, per an embodiment, this thus means in other words that the received synchronization signals are preferably generated a) by tapping a periodic signal at the synchronization output of the generator of the plasma-generating device, or b) by measuring the periodic voltage signal at the chamber of the plasma-generating device by way of the voltmeter.

According to a further preferred refinement of the disclosure, per an embodiment, it is preferably provided that the device for detecting the optical signal and for transmitting the detected optical signal to the photomultiplier comprises an optical fiber. This makes transmitting the optical signal to the photomultiplier particularly simple. In particular, it is provided that the optical fiber leads from an interior of the chamber via the optical passage into the area outside the chamber, so that the chamber is connected via the optical passage to the photomultiplier.

In this context, it is provided according to a further preferred refinement of the disclosure, per an embodiment, that an end of the optical fiber arranged in the chamber comprises an optics unit for detecting the incident optical signal. Accordingly, even weak emissions of the plasma can be transmitted particularly easily as optical signals to the photomultiplier.

It is likewise provided according to a further preferred refinement of the disclosure, per an embodiment, that the end of the optical fiber arranged in the chamber is displaceable with respect to the chamber inside the chamber. This enables a location-resolved measurement of the plasma emission in a simple manner. Moreover, the point of maximum emission can be determined in this way, by which the signal-to-noise ratio can be improved and in this way the integration time can be reduced.

According to a further preferred refinement of the disclosure, per an embodiment, it is moreover provided that the device comprises an optical filter arranged before the photomultiplier in the signal direction for selecting a wavelength of the optical signal. In the present case, “in the signal direction” preferably means the direction of the optical signal conducted through the device—thus from the plasma to the photomultiplier. Accordingly, this preferably also means that an optical filter for a specific wavelength is interconnected between the end of the optical fiber arranged outside the chamber and an input for the optical signal of the photomultiplier. This enables wavelength-specific emissions of the plasma to be able to be studied.

In this context, it is provided according to a further preferred refinement of the disclosure, per an embodiment, that the device comprises a monochromator and/or interferometer arranged before the photomultiplier in the signal direction for selecting a wavelength of the optical signal. The end of the optical fiber arranged outside the chamber preferably has a focusable collimator for this purpose, in order to conduct the optical signal coming out of the optical fiber into an entry gap of the monochromator. The monochromator preferably has a dispersing element or an optical grating for diverging the optical signal according to the wavelength. Alternatively, the interferometer can be used for selecting the wavelength. The monochromator and/or the interferometer has the advantage over the above-described variant having a filter that the wavelength to be selected can be changed easily.

Furthermore, it can preferably also be provided that the device comprises more than one photomultiplier for simultaneously measuring multiple wavelengths. In this regard, it is furthermore preferably provided that a multi-arm optical fiber is used for splitting the optical signal, so that one optical signal detected in the chamber is transmitted to multiple photomultipliers.

Furthermore, it is preferably provided that the end of the optical fiber in the plasma-generating device is protected from coating by a protective device. This increases the lifetime of the device. According to a further preferred refinement of the disclosure, per an embodiment, it is provided that the device is free of an ICCD camera. Accordingly, the chamber of the plasma-generating device is also free of a viewing window for the ICCD camera.

With respect to the evaluation unit, it is provided according to a further preferred refinement of the disclosure, per an embodiment, that the evaluation unit comprises an oscilloscope or FPGA (field programmable gate array). Furthermore, it can preferably be provided that the evaluation unit also comprises a measuring computer connected to the oscilloscope or FPGA. Oscilloscopes or FPGAs are particularly suitable for receiving the chronologically successive voltage signals and the synchronization signal. Moreover, oscilloscopes and/or FPGAs also enable an assignment of the received voltage signals to the respective time interval within the period of the periodic signal with the aid of the received synchronization signal particularly easily. It is likewise possible that the oscilloscope or the FPGA is used to digitize the received signals, the step of assignment is carried out by the measuring computer.

In this context, it is moreover provided in a further preferred refinement of the disclosure, per an embodiment, that the evaluation unit, and particularly preferably the oscilloscope or the FPGA, has a time resolution of less than or equal to 10 ns. This makes the evaluation unit particularly suitable for processing high-frequency signals.

According to a further preferred refinement of the disclosure, per an embodiment, it is provided that a pulse width of the photomultiplier is less than the period of the periodic signal. A pulse width less than the period of the periodic signal is not necessary to carry out the method, but has the advantage that multiple photons can be counted per period. The integration time of the system until reaching a usable result can be significantly reduced by the evaluation of multiple photons per unit of time.

With respect to the photomultiplier, it is moreover provided according to a further preferred refinement that the photomultiplier has a chronological variation in the time response—also called time jitter—of less than or equal to 500 ps. This enables a particularly accurate assignment of the received voltage signals to the respective time interval within the period of the periodic signal to be able to be carried out with the aid of the received synchronization signal in the evaluation unit, and accordingly a particularly precise measurement of the emission of the plasma.

### BRIEF DESCRIPTION OF THE FIGURES

The invention is explained by way of example hereinafter with reference to the appended drawings on the basis of preferred exemplary embodiments, wherein the features described hereinafter can represent an aspect of the invention both individually and in combination. In the figures:

FIG. 1 shows a schematic representation of a device for detecting an intensity of an emission of a plasma according to an embodiment of the disclosure,

FIG. 2 shows a schematic representation of the device for detecting the intensity of an emission of the plasma according to an embodiment of the disclosure, and

FIG. 3 shows a schematic representation of method steps of a measuring method that can be carried out using the device from FIG. 1 or 2.

### DETAILED DESCRIPTION

FIG. 1 shows a schematic representation of a device 10 for detecting an intensity of an emission 12 of a plasma 14 according to an embodiment of the disclosure. The device 10 comprises a plasma-generating device 16, a photomultiplier 18, a synchronization signal generator 20, and an evaluation unit 22. The plasma-generating device 16 comprises a chamber 24 for providing the plasma 14 and a generator 26 for generating a periodic signal—in the present case an AC voltage as a periodic high-frequency signal.

The synchronization signal generator 20 is configured to generate at least one synchronization signal correlating with the periodic signal. In the embodiment shown in FIG. 1, the generator 26 is directly also used as the synchronization signal generator 20, wherein the synchronization signal is tapped via the synchronization output of the generator 20.

Furthermore, the chamber 24 is connected via an optical passage 28 to the photomultiplier 18 such that an optical signal generated by the plasma 14 is transmittable to the photomultiplier 18.

As shown in the present case in FIG. 1, the device 10 has an optical fiber 30, which leads from an interior of the chamber 24 via the optical passage 28 to the area outside the chamber 24. An end of the optical fiber 30 arranged in the chamber 24 moreover has an optics unit 32 for detecting the incident optical signal. It is also apparent that an optical filter 34 for a specific wavelength is interconnected between the end of the optical fiber 30 arranged outside the chamber 24 and an input for the optical signal of the photomultiplier 18.

The photomultiplier 18 is configured to generate a voltage signal on the basis of the optical signal. For this purpose, the photomultiplier 18 is operable in the photon counting mode.

As is apparent in FIG. 1, the evaluation unit 22 is connected to the photomultiplier to receive the voltage signal and to the synchronization signal generator 20 to receive the synchronization signal. It can also be seen in FIG. 1 that in the present case the evaluation unit 22 is embodied as a combination of an oscilloscope 23 for receiving the voltage signals and the synchronization signal and a measuring computer 36 for evaluating the recorded data.

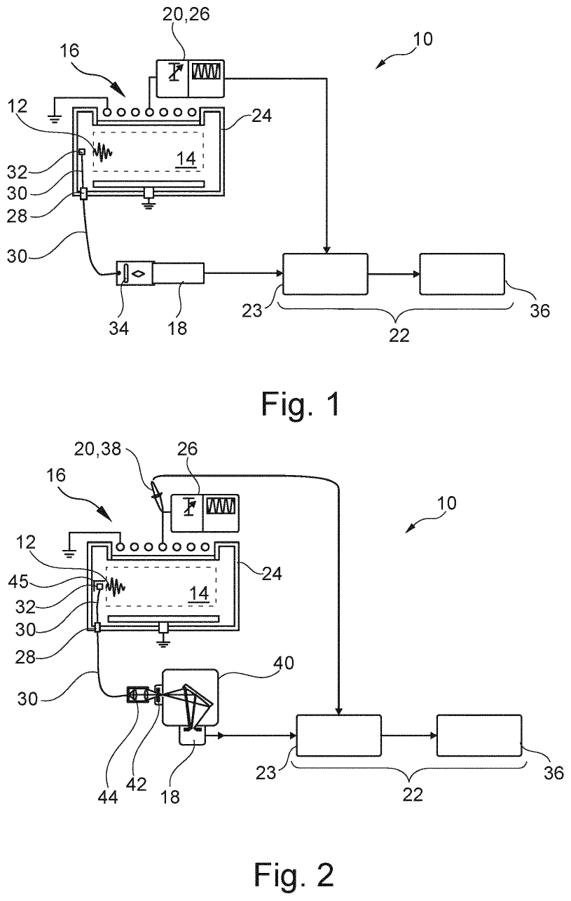

FIG. 2 shows a schematic representation of the device 10 for detecting the intensity of an emission 12 of the plasma 14 according to an embodiment of the disclosure. The embodiment shown in FIG. 2 is constructed similarly to the embodiment shown in FIG. 1, so that only the differences from the embodiment shown in FIG. 1 will be discussed hereinafter:

In the embodiment shown in FIG. 2, the synchronization signal generator 20 is not formed by the generator 26 of the plasma-generating device 16, but rather by a voltmeter 38 connected to the chamber 24. Moreover, the device 10 for selecting the wavelength does not have an optical filter 34, but rather a monochromator 40. To conduct the optical signal coming out of the optical fiber 30 into an entry gap 42 of the monochromator 40, the end of the optical fiber 30 arranged outside the chamber 24 has a focusable collimator 44. A displacement device 45 is also schematically indicated in FIG. 2, using which the optics unit 32 for detecting the incident optical signal is displaceable in the chamber 24.

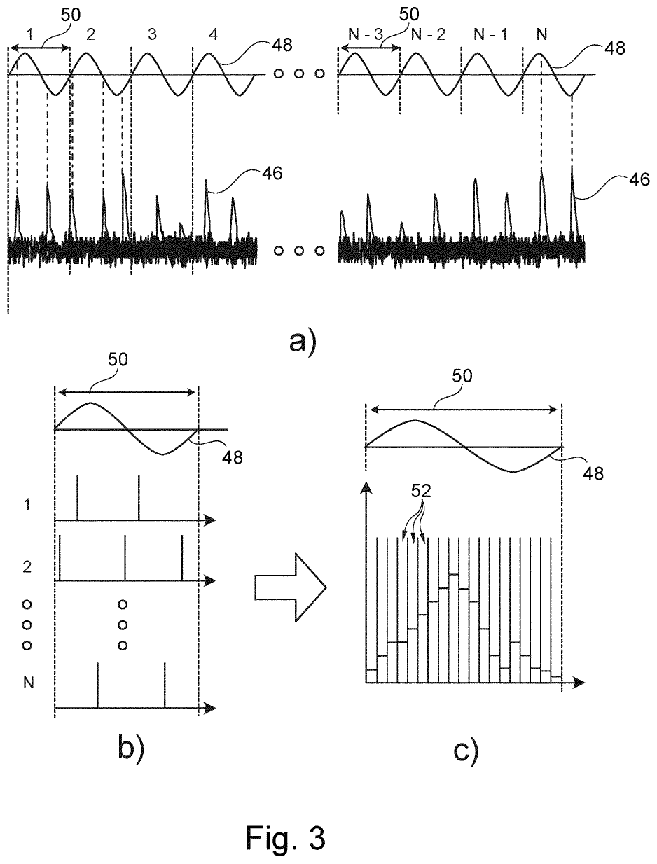

The evaluation unit 22 shown in FIGS. 1 and 2 is moreover configured to carry out the method described hereinafter with reference to FIG. 3 for detecting an intensity of an emission 12 of the plasma 14.

In a first step of the method, the evaluation unit 22 receives chronologically successive voltage signals 46 of the photomultiplier 18 used for detecting the optical signals of the plasma. A schematic representation of the chronologically successive voltage signals 46 received by the evaluation unit 22 is shown in the lower half of FIG. 3a), wherein each jag corresponds to a voltage signal 46 generated by a photon incident on the photomultiplier 18.

In a further step of the method, the evaluation unit 22 receives at least one synchronization signal correlating with the periodic signal 48 of the plasma-generating device 16. The periodic signal 48 of the plasma-generating device 16 is shown in the upper half of FIG. 3a), wherein the arrow 50 identifies a period 50 of the periodic signal 48. N indicates the number of periods 50 and can assume values of several million.

In a further step of the method, the evaluation unit 22 assigns the received voltage signals 46 with the aid of the received synchronization signal to a corresponding time interval 52 within a period 50 of the periodic signal 48. This is performed in the present case—as schematically shown in FIG. 3—in that the voltage signals 46 are assigned in the evaluation unit 22 with the aid of the synchronization signal to the phase of the periodic signal 48 and subsequently sorted according to their assignment into the predefined time intervals 52. In the present case, the predefined time interval 52 has a length of 2 ns in each case. Moreover, noise is filtered out in this step, since only signals the amplitude of which reaches a certain limiting value are evaluated.

By summing a number of voltage signals 48 assigned to the respective time interval 52, the histogram shown as an example in FIG. 3c) results, which corresponds to the determined intensity of the emission.

As used herein, the terms “general,” “generally,” and “approximately” are intended to account for the inherent degree of variance and imprecision that is often attributed to, and often accompanies, any design and manufacturing process, including engineering tolerances, and without deviation from the relevant functionality and intended outcome, such that mathematical precision and exactitude is not implied and, in some instances, is not possible.

All the features and advantages, including structural details, spatial arrangements and method steps, which follow from the claims, the description and the drawing can be fundamental to the invention both on their own and in different combinations. It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

### LIST OF REFERENCE NUMERALS

10 device
12 emission
14 plasma
16 plasma-generating device
18 photomultiplier
20 synchronization signal generator
22 evaluation unit
23 oscilloscope
24 chamber
26 generator
28 optical passage
30 optical fiber
32 optics unit
34 optical filter
36 measuring computer
38 voltmeter
40 monochromator
42 entry gap
44 focusable collimator
45 displacement device
46 voltage signals
48 periodic signal of the plasma-generating device
50 arrow, period
52 time interval

1. A method for detecting an intensity of an emission of a plasma that can be generated in a plasma-generating device, the method comprising the following steps:
receiving chronologically successive voltage signals of a photomultiplier used for detecting optical signals of the plasma,
receiving at least one synchronization signal correlating with a periodic signal of the plasma-generating device,
assigning the received voltage signals to a respective time interval within a period of the periodic signal with the aid of the received synchronization signal, and
determining the intensity by summing a number of voltage signals assigned to the respective time interval.

2. The method as claimed in claim 1, wherein
a) the step of receiving at least one synchronization signal correlating with the periodic signal of the plasma-generating device comprises receiving multiple pulses chronologically correlating with the periodic signal of the plasma-generating device or receiving a periodic synchronization signal over multiple periods and the step of assigning the received voltage signals to the respective time interval within the period of the periodic signal with the aid of the received synchronization signal comprises assigning the received voltage signals to the respective time interval within the period of the periodic signal with the aid of the multiple received pulses or with the aid of the periodic synchronization signal, or
b) the step of receiving at least one synchronization signal correlating with the periodic signal of the plasma-generating device comprises receiving a starting phase signal of the plasma-generating device and the step of assigning the received voltage signals to the respective time interval within the period of the periodic signal with the aid of the received synchronization signal comprises assigning the received voltage signals to the respective time interval within the period of the periodic signal with the aid of the received starting phase signal, a time of the received voltage signal, and a period duration of the periodic signal.

3. An evaluation unit of a device for detecting an intensity of an emission of a plasma that can be generated in a plasma-generating device, wherein the evaluation unit is configured to carry out the method as claimed in claim 2.

4. A device for detecting an intensity of an emission of a plasma that can be generated in a plasma-generating device comprising the plasma-generating device a photomultiplier a synchronization signal generator and an evaluation unit designed as claimed in claim 3,
wherein the plasma-generating device comprises a chamber for providing the plasma and a generator for generating a periodic signal and is designed to generate a plasma in the chamber,
wherein the chamber is connected via an optical passage to the photomultiplier such that an optical signal generated by the plasma is transmittable to the photomultiplier,
wherein the photomultiplier is configured to generate a voltage signal on the basis of the optical signal,
wherein the synchronization signal generator is configured to generate at least one synchronization signal correlating with the periodic signal, and
wherein the evaluation unit is connected to the photomultiplier to receive the voltage signal and to the synchronization signal generator to receive the synchronization signal.

5. The device as claimed in claim 4, wherein the synchronization signal generator is formed by the generator, or wherein the synchronization signal generator is formed by a voltmeter connected to the chamber.

6. The device as claimed in claim 4, wherein the device comprises an optical fiber for detecting the optical signal and for transmitting the detected optical signal to the photomultiplier.

7. The device as claimed in claim 6, wherein an end of the optical fiber arranged in the chamber comprises an optics unit for detecting the incident optical signal, and/or is displaceable in relation to the chamber inside the chamber.

8. The device as claimed in claim 4, wherein the device comprises an optical filter arranged before the photomultiplier in the signal direction for selecting a wavelength of the optical signal, and/or
wherein the device comprises a monochromator and/or interferometer arranged before the photomultiplier in the signal direction for selecting a wavelength of the optical signal.

9. The device as claimed in claim 4, wherein the device is free of an ICCD camera.

10. The device as claimed in claim 4, wherein the evaluation unit comprises an oscilloscope or FPGA and/or wherein the evaluation unit has a time resolution of less than or equal to 10 ns.

11. The device as claimed in claim 4, wherein a pulse width of the photomultiplier is less than the period of the periodic signal, and/or
wherein the photomultiplier has a chronological variation in the time response of less than or equal to 500 ps.
